(19) United States
(12) Patent Application Publication
(10) Pub. No.: US 2013/0312816 A1
(43) Pub. Date: Nov. 28, 2013

(54) TANDEM TYPE INTEGRATED PHOTOVOLTAIC MODULE AND MANUFACTURING METHOD THEREOF

(71) Applicants: La-Sun Jeon, Seoul (KR); Seung-Yeop Myong, Seoul (KR)

(72) Inventors: La-Sun Jeon, Seoul (KR); Seung-Yeop Myong, Seoul (KR)

(21) Appl. No.: 13/477,687

(22) Filed: May 22, 2012

(51) Int. Cl. H01L 31/0687; H01L 31/18

(52) U.S. Cl. 136/255; 438/72; 257/E31.053

(57) ABSTRACT

Disclosed is a tandem type integrated photovoltaic module. The tandem type integrated photovoltaic module includes a first cell and a second cell, all of which are formed respectively by stacking on a substrate a lower electrode, a photoelectric conversion layer and an upper electrode, wherein the photoelectric conversion layer comprises a first unit cell layer, a second unit cell layer and an intermediate reflector located between the first unit cell layer and the second unit cell layer; wherein the lower electrode of the first cell and the lower electrode of the second cell are separated by a lower electrode separation groove, and wherein a plurality of through holes are formed to be spaced from each other in the photoelectric conversion layer on the lower electrode of the first cell in order to connect the upper electrode of the second cell with the lower electrode of the first cell.

### FIELD OF THE INVENTION

The present invention relates to a tandem type integrated photovoltaic module and a manufacturing method thereof.

### BACKGROUND OF THE INVENTION

Recently, as existing energy resources like oil and coal and the like are expected to be exhausted, much attention is increasingly paid to alternative energy sources which can be used in place of the existing energy sources. As an alternative energy sources, sunlight energy is abundant and has no environmental pollution. Therefore, more and more attention is paid to the sunlight energy.

A photovoltaic module converting sunlight energy into electrical energy has a junction structure of a p-type semiconductor and an n-type semiconductor. When light is incident on the photovoltaic module, an electron with a negative electric charge and a hole with a positive electric charge are generated by interaction between the light and a material constituting the semiconductor of the photovoltaic module. Then, electric current flows while the electron and the hole move.

Depending on the thickness of the semiconductor of the photovoltaic module, the photovoltaic module is classified into a bulk type photovoltaic module and a thin-film type photovoltaic module. The thin-film type photovoltaic module includes a photovoltaic material layer of which the thickness is equal to or less than from several tens of micrometers to several micrometers.

At present, a bulk type silicon photovoltaic module is mainly and widely used for ground power. However, the recent increase of the demand for the bulk type silicon photovoltaic module is now increasing its price due to the lack of its raw material.

Therefore, in recent times, providing an integrated thin-film photovoltaic module has become the most important issue, which has high energy conversion efficiency and can be mass produced at a low cost. However, a single-junction thin-film photovoltaic module is limited in its achievable performance. Accordingly, a double junction thin-film photovoltaic module or a triple junction thin-film photovoltaic module having a plurality of stacked unit cells has been developed, pursuing high stabilized efficiency. The double junction thin-film photovoltaic module and the triple junction thin-film photovoltaic module are called a tandem type photovoltaic module.

In addition to this, researches are now being devoted to an integration technology for the photovoltaic module in order to improve the efficiency of the thin-film photovoltaic module by reducing the ineffective area thereof.

### SUMMARY OF THE INVENTION

One aspect of the present invention is a tandem type integrated photovoltaic module. The tandem type integrated photovoltaic module includes a first cell and a second cell, all of which are formed respectively by stacking on a substrate a lower electrode, a photoelectric conversion layer and an upper electrode, wherein the photoelectric conversion layer comprises a first unit cell layer, a second unit cell layer and an intermediate reflector located between the first unit cell layer and the second unit cell layer; wherein the lower electrode of the first cell and the lower electrode of the second cell are separated by a lower electrode separation groove, and wherein a plurality of through holes are formed to be spaced from each other in the photoelectric conversion layer on the lower electrode of the first cell in order to connect the upper electrode of the second cell with the lower electrode of the first cell.

Another aspect of the present invention is a manufacturing method of a tandem type integrated photovoltaic module. The manufacturing method includes: forming a lower electrode layer on a substrate; forming a lower electrode separation groove separating the lower electrode layer into a first cell lower electrode layer and a second cell lower electrode layer; forming a photoelectric conversion layer including a first unit cell layer, an intermediate reflector and a second unit cell layer on the first cell lower electrode layer and a second cell lower electrode layer; forming a plurality of through holes which are spaced from each other and penetrate through the photoelectric conversion layer on the first cell lower electrode layer; forming an upper electrode layer within the through hole and on the photoelectric conversion layer; and forming an upper separation groove which separates the upper electrode layer and the photoelectric conversion layer and of which a portion passes over the lower electrode separation groove.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a perspective view showing a tandem type integrated photovoltaic module including photovoltaic cells which are connected in series through a point contact in accordance with an embodiment of the present invention;

FIGS. 2a and 2b are cross sectional views taken along lines a-a′ and b-b′ of FIG. 1;

FIGS. 3a to 3i show a manufacturing process of a tandem type integrated photovoltaic module according to the embodiment of the present invention;

FIGS. 4a and 4b show intensity distributions of a laser beam before and after passing through a homogenizer and show pattern surfaces according to the intensity distributions;

FIG. 4c shows a section of a pattern formed by the laser beam which has passed through the homogenizer;

FIG. 5 shows an enlarged view of a dotted-line quadrangular part “A” of FIG. 1 according to the embodiment of the present invention;

FIGS. 6a and 6b show enlarged views of a dotted-line quadrangular part “A” of FIG. 1 according to another embodiment of the present invention;

FIGS. 7a and 7b are cross sectional views taken along line c-c′ of FIG. 6a and line d-d′ of FIG. 6b respectively.

FIGS. 8a to 8c show a shape of a second line surrounding a through-hole according to the embodiment of the present invention.

### DETAILED DESCRIPTION

Hereafter, an exemplary embodiment of the present invention will be described in detail with reference to the accompanying drawings. Here, the embodiment of the present invention can be variously transformed, and the scope of the present invention is not limited to the following embodiment. The shapes and sizes of the components in the drawings may be exaggerated for clarity of the description. It is noted that the same reference numerals are used to denote the same elements throughout the drawings. In the following description of the present invention, the detailed description of known functions and configurations incorporated herein is omitted when it may make the subject matter of the present invention unclear.

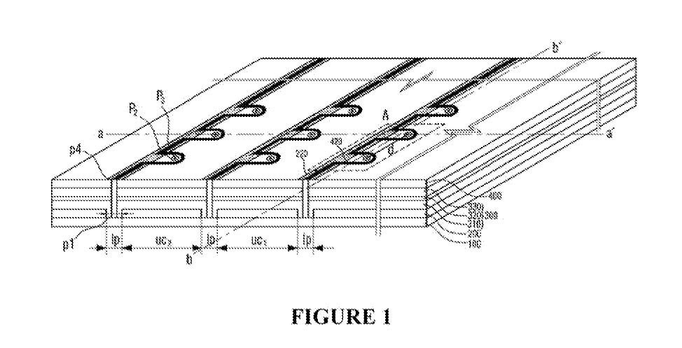

FIG. 1 is a perspective view showing a photovoltaic module including photovoltaic cells which are connected in series through a point contact in accordance with a first embodiment of the present invention. Here, the shapes of a lower electrode separation groove P₁, an insulating groove P₂, a through hole P₃ and an upper separation groove P₄ are shown on the upper surface of the photovoltaic module in FIG. 1 and the following figures for convenience of description. The shapes may not be observed on the upper surface.

The photovoltaic module according to the first embodiment of the present invention includes a substrate 100, a lower electrode 200, a photoelectric conversion layer 300 and an upper electrode 400.

Here, the photoelectric conversion layer 300 may include a plurality of unit cell layers. For example, the photoelectric conversion layer 300 may include two stacked unit cell layers or three stacked unit cell layers. Each of the stacked unit cell layers is a basic unit layer capable of performing photoelectric conversion.

An intermediate reflector may be inserted between the stacked unit cell layers in order to maximize light trapping effect by enhancing internal reflection. For example, when the photoelectric conversion layer 300 includes two unit cell layers 310 and 330, the intermediate reflector 320 may be inserted between the two unit cell layers. Since the intermediate reflector 320 is located between the two unit cell layers, the intermediate reflector 320 may include a light transmitting material. The light transmitting material may include at least one of ZnO, ITO, SiO and SnO₂.

When the photoelectric conversion layer 300 includes a plurality of unit cell layers, each of the photovoltaic cells UC₁ and UC₂ connected in series to each other may have a structure formed by stacking a plurality of the unit cell layers 310 and 330. The open circuit voltage of the photovoltaic cell UC₁ and UC₂ is the sum of the open circuit voltages of the stacked unit cell layers 310 and 330. The short-circuit current of the unit cell UC₁ and UC₂ is a minimum value among the short-circuit currents of the stacked unit cell layers 310 and 330.

As shown in FIG. 1, the lower electrode separation groove P₁ is formed to penetrate through the lower electrode 200 so as to prevent the short circuit between the lower electrodes 200 of each photovoltaic cell. The lower electrode separation groove P₁ may be, for example, formed along a straight first line 220.

A plurality of through-holes P₃ penetrating the photoelectric conversion layer 300 are spaced from each other in the form of a point having a predetermined width instead of a straight line and formed on one side of the lower electrode separation groove P₁. Adjacent photovoltaic cells UC₁ and UC₂ are connected in series with each other through the through hole P₃. That is, the lower electrode 200 of a first cell UC₁ is connected with the upper electrode 400 of a second cell UC₂ through the point type through hole P₃, so that the first cell UC₁ is connected in series with the second cell UC₂.

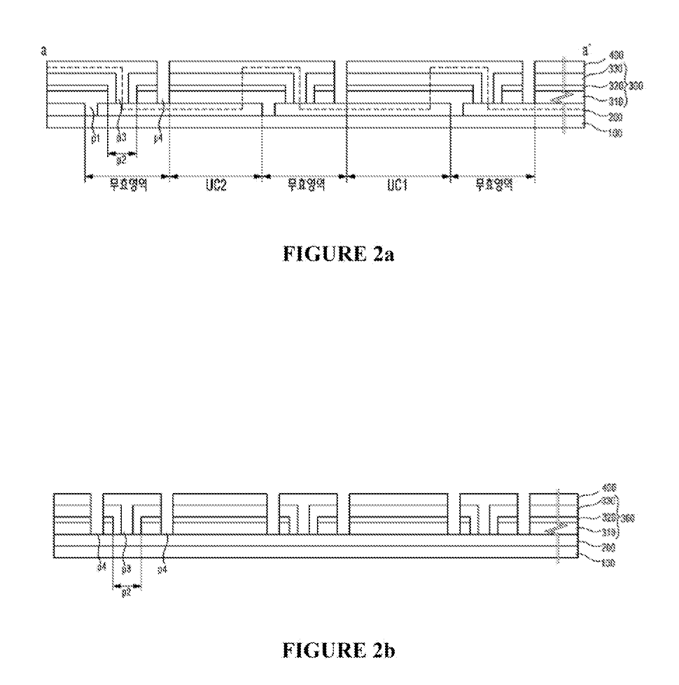

It can be seen that the aforementioned fact is shown in FIG. 2a which is a cross sectional view of the photovoltaic module taken along line a-a′ of FIG. 1. As shown in FIG. 2a, the adjacent cells UC₁ and UC₂ can be connected in series with each other through a portion where the through holes P₂ are formed to be spaced from each other.

While it is described in this specification that the through hole P₃ is formed in the form of a point, this is just an example. As long as the plurality of the through holes P₃ are spaced from each other, this is included in the scope of the present invention. For example, the through hole P₃ may have a cut and divided straight line shape extending in one direction.

As described above, the photovoltaic module according to the embodiment of the present invention includes the lower electrode 200, the photoelectric conversion layer 300 and the upper electrode 400, and may include the plurality of the unit cells UC₁ and UC₂ connected in series with each other.

The upper separation groove P₄ is formed to penetrate through the photoelectric conversion layer 300 and the upper electrode 400, and then the photovoltaic cells UC₁ and UC₂ are separated. With the exception of a portion where the upper separation groove P₄ surrounds the point type through hole P₃ in a predetermined shape, the upper separation groove P₄ is formed to be overlapped with the path of the lower electrode separation groove P₁. For example, the upper separation groove P₄ may be formed along a second line 420.

For the purpose of understanding the present invention, FIG. 2b shows a cross sectional view of the photovoltaic module taken along line b-b′ of FIG. 1. As shown in FIG. 1, a portion of the upper separation groove P₄, which passes over the lower electrode separation groove P₁, extends up to the upper surface of the substrate 100. On the other hand, as shown in FIG. 2b, a portion of the upper separation groove P₄, which does not pass over the lower electrode separation groove P₁, extends only up to the upper surface of the lower electrode 200. This is because while the upper separation groove P₄ is formed to penetrate through the photoelectric conversion layer 300 and the upper electrode 400, the lower electrode 200 of the forming portion of the lower electrode separation groove P₁ has been already removed by the lower electrode separation groove P₁.

As described above, since the first line 220 in which the lower electrode separation groove P₁ is formed and the second line 420 in which the upper separation groove P₄ is formed are overlapped with each other with the exception of a particular area, the ineffective area of the photovoltaic module according to the embodiment of the present invention may be reduced. Also, since the through hole P₃ for connecting in series the unit cells within the photovoltaic module is formed separately from each other at a predetermined interval in the form of the point contact, the ineffective area of the photovoltaic module can be reduced. Therefore, the effective area compared to the same area is increased, so that a relative current value is increased.

According to the embodiment of the present invention, even though the intermediate reflector 320 is formed of a conductive material, it is possible to prevent leak current generated through the intermediate reflector 320. This can be obtained by the insulating groove which is formed in the intermediate reflector 320 and denoted by “P₂” in FIGS. 1, 2a and 2b, and insulates the through hole P₃ from the intermediate reflector 320.

When the photovoltaic module is observed from the upper electrode 400, the section of the insulating groove P₂ has a width greater than that of the through hole P₃, so that the through hole P₃ passes through the inside of the insulating groove P₂. Accordingly, the insulating groove P₂ prevents the through hole P₃ from contacting with the intermediate reflector 320. Therefore, it is possible to prevent leak current generated from the contact of the material of the upper electrode 400 with the intermediate reflector 320 through the through hole P₃.

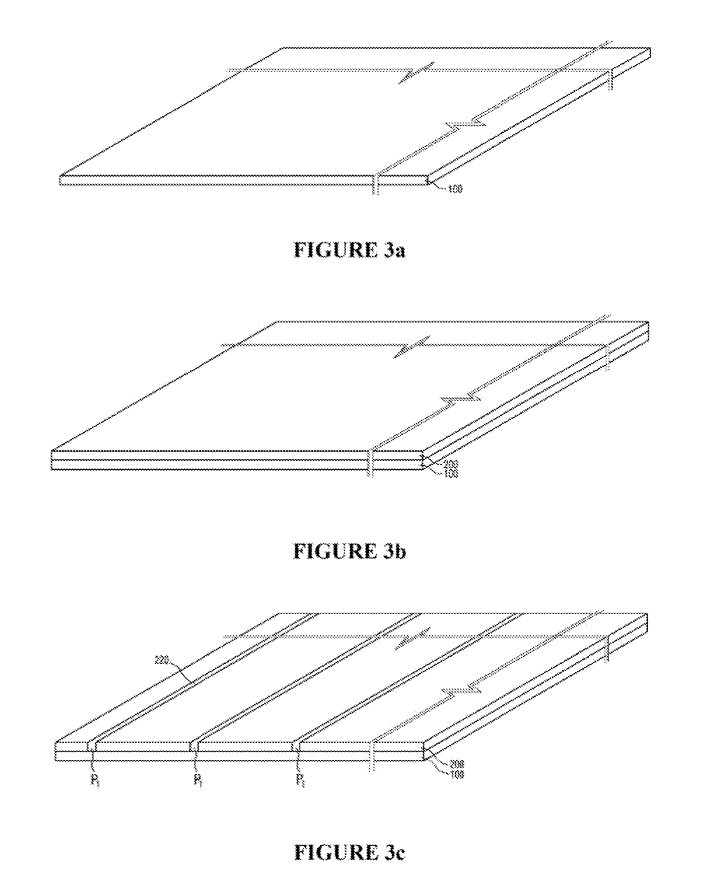

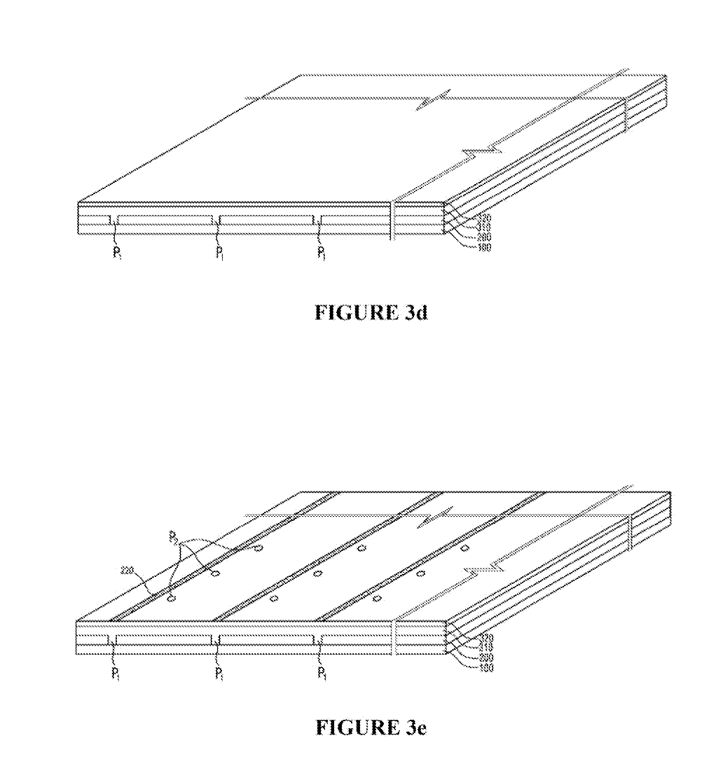

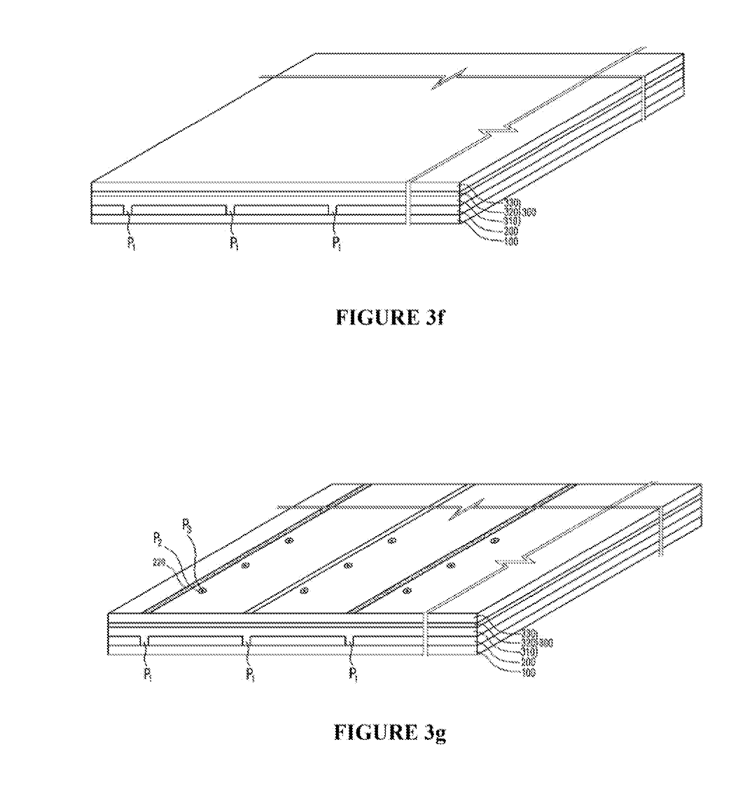

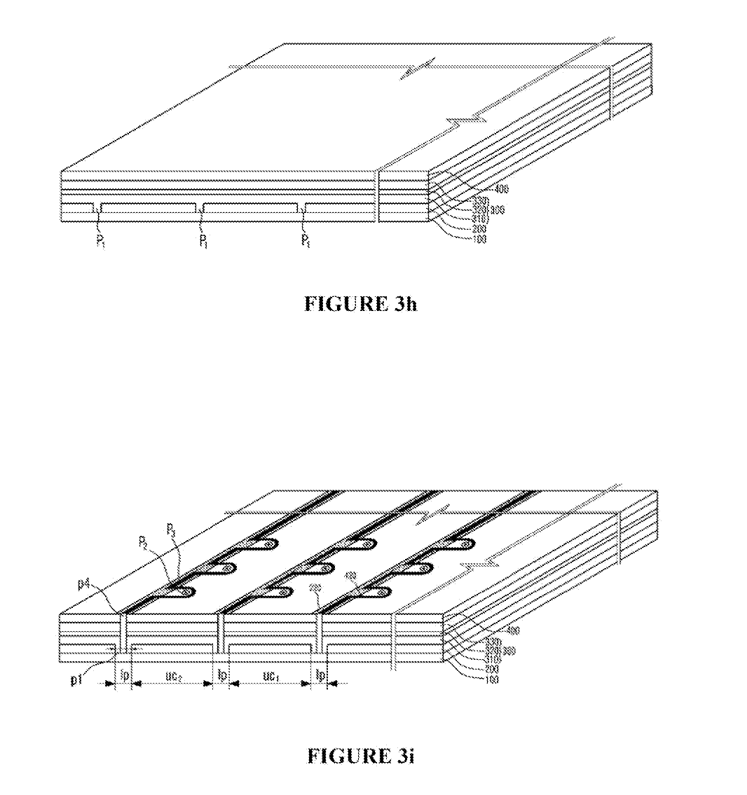

Hereafter, a manufacturing process of a photovoltaic module including the photovoltaic cells connected in series to each other by the point contact in accordance with the first embodiment of the present invention will be described in detail with reference to FIGS. 3a to 3i. Although FIGS. 3a to 3i show three photovoltaic cells, the photovoltaic module of the present invention may include a larger number of the cells.

As shown in FIG. 3a, the substrate 100 is provided. The substrate 100 may be an insulating transparent substrate. When the photovoltaic module according to the embodiment of the present invention performs photoelectric conversion by light irradiated from the upper electrode 400, the substrate 100 may be an insulating opaque substrate. The substrate 100 may be a flexible substrate.

As shown in FIG. 3b, the lower electrode 200 is formed on the substrate 100. The lower electrode 200 may be a transparent conductive electrode including SnO₂, ZnO and ITO and the like. When the photovoltaic module according to the embodiment of the present invention performs photoelectric conversion by light irradiated from the upper electrode 400, the lower electrode 200 may be an opaque electrode.

As shown in FIG. 3c, the lower electrode 200 is scribed by irradiating laser from the air to the lower electrode 200 or the substrate 100. The lower electrode separation groove P₁ separating the lower electrode 200 may be hereby formed, for example, along the straight first line 220. That is, the lower electrode 200 is separated by the lower electrode separation groove P₁, thereby preventing the short-circuit between the adjacent lower electrodes 200. As shown in FIG. 3d, the first unit cell layer 310 and the intermediate reflector 320 are formed on the lower electrode 200. Here, the first unit cell layer 310 and the intermediate reflector 320 can be also formed in the lower electrode separation groove P₁.

The first unit cell layer 310 and the second unit cell layer 330 to be subsequently formed on the intermediate reflector 320 may include any material converting incident light energy into electrical energy. For example, the first and the second unit cell layers 310 and 330 include a photovoltaic material capable of forming a thin-film type photovoltaic module such as an amorphous silicon solar cell, a compound solar cell, an organic solar cell and a dye sensitized solar cell.

The intermediate reflector 320 reflects a part of light which has transmitted through a unit cell layer on which the light is first incident among the first unit cell layer and the second unit cell layer to be subsequently formed, to the unit cell layer on which light is first incident, and passes a part of the light through the other unit cell layer. As a result, the amount of the light absorbed by the unit cell layer on which the light is first incident is increased, so that electric current generated from the unit cell layer can be increased.

As shown in FIG. 3e, the insulating grooves P₂ penetrating through the intermediate reflector 320 and the first unit cell layer 310 may be formed separately from each other. In accordance with the embodiment of the present invention, the insulating groove P₂ may be formed to penetrate through the intermediate reflector 320. The insulating groove P₂ prevents the through hole P₃ to be formed subsequently from contacting with the intermediate reflector 320.

As shown in FIG. 3f, the second unit cell layer 330 is formed on the intermediate reflector 320. Here, the insulating groove P₂ may be filled with the material of the second unit cell layer 330.

Here, among the first and the second unit cell layers, the optical band gap of one unit cell layer closer to a light incident side than the other may be larger than that of the other unit cell layer. For example, when light is incident through the substrate 100, the optical band gap of the first unit cell layer is larger than that of the second unit cell layer. This is because light with a short wavelength having a high energy density has a short light transmission distance, and a material having a larger optical band gap absorbs more light with a short wavelength.

When the first and the second unit cell layers include an amorphous silicon based photovoltaic material, according to another embodiment of the present invention, the insulating groove P₂ may be formed to penetrate through other layers other than the intermediate reflector 320.

That is, the first and the second unit cell layers include a p-type semiconductor layer, an intrinsic semiconductor layer and an n-type semiconductor layer, all of which are stacked in the order listed. According to the embodiment, the first and the second unit cell layers may include the n-type semiconductor layer, the intrinsic semiconductor layer and the p-type semiconductor layer, all of which are stacked in the order listed.

Here, the insulating groove P₂ may be formed to penetrate through not only the intermediate reflector 320 but also the p-type semiconductor layer contacting with the intermediate reflector 320. When the p-type semiconductor layer, the intrinsic semiconductor layer and the n-type semiconductor layer are stacked on the unit cell layer in the order listed, the insulating groove P₂ may be formed to penetrate through the intermediate reflector 320 and the p-type semiconductor layer of the second unit cell layer. In this case, according to the embodiment, the insulating groove P₂ is able to penetrate through the first unit cell layer 310.

When the n-type semiconductor layer, the intrinsic semiconductor layer and the p-type semiconductor layer are stacked on the unit cell layer in the order listed, the insulating groove P₂ may be formed to penetrate through the intermediate reflector 320 and the p-type semiconductor layer of the first unit cell layer. In this case, according to the embodiment, the insulating groove P₂ is able to penetrate through the n-type semiconductor layer and the intrinsic semiconductor layer of the first unit cell layer.

This is because when the p-type semiconductor layer contacts with the upper electrode 400 through the through hole P3, the p-type semiconductor layer has high conductivity, so that there is a possibility that leak current is generated. Therefore, in forming the insulating groove P₂, it is possible to prevent the leak current generation by allowing the insulating groove P₂ to also penetrate through the p-type semiconductor layer contacting with the intermediate reflector 320.

While the foregoing has described the photoelectric conversion layer 300 including the two unit cell layers 310 and 330 and intermediate reflector 320 formed between the two unit cell layers 310 and 330, three or more unit cell layers may be included in the photoelectric conversion layer 300. Further, two or more intermediate reflectors may be included in the photoelectric conversion layer 300 in accordance with the embodiment of the present invention. Here, the insulating groove can be formed to penetrate through all of the intermediate reflectors.

In general, the unit cell layers of the photoelectric conversion layer 300 are formed in vacuum, and laser patterning for forming the lower electrode separation groove P₁, the insulating groove P₂, the through hole P₃ and the upper separation groove P₄ is performed in atmospheric air. Therefore, with regard to FIG. 3, in order to perform the laser patterning forming the through hole P₃ to be described below, it is necessary for the photoelectric conversion layer 300 to be exposed to the atmosphere. Here, for a time during which the photoelectric conversion layer 300 is exposed to the atmosphere, the photoelectric conversion layer 300 is oxidized and may be deteriorated. Consequently, the efficiency of the manufactured photovoltaic module may be degraded.

Accordingly, in the manufacture of the photovoltaic module according to another embodiment of the present invention, after the forming of the photoelectric conversion layer 300 in vacuum and before the forming of the through hole P₃ in atmospheric air, a forming of the transparent conductive layer on the photoelectric conversion layer in vacuum can be further included. As such, it is possible to prevent the photoelectric conversion layer 300 from being deteriorated by being exposed to the atmosphere. For example, since the transparent conductive layer is formed on the photoelectric conversion layer 300, the photoelectric conversion layer 300 can be prevented from being oxidized during the process of the laser scribing in the atmosphere.

The transparent conductive layer cannot only, as described above, protect the photoelectric conversion layer 300 but also maximize light trapping effect between the photoelectric conversion layer 300 and the upper electrode 400. In other words, the transparent conductive layer reflects light which is not used in the photovoltaic conversion in the photoelectric conversion layer 300 and causes the light to be reused in the photoelectric conversion layer 300, thereby improving the light efficiency. The transparent conductive layer may include, for example, ZnO or ITO.

Hereafter, although it is described that the through hole P₃ penetrates through only the photoelectric conversion layer 300, the through hole P₃ may be formed to penetrate through the photoelectric conversion layer 300 and the transparent conductive layer formed on the photoelectric conversion layer 300 in accordance with embodiments. Further, although it is described that the upper separation groove P₄ penetrates through the photoelectric conversion layer 300 and the upper electrode 400, the upper separation groove P₄ may be formed to penetrate through the photoelectric conversion layer 300, the transparent conductive layer and the upper electrode 400 in accordance with embodiments.

As shown in FIG. 3g, laser is irradiated in the atmosphere to the substrate 100 or the photoelectric conversion layer 300, so that the photoelectric conversion layer 300 is scribed. As a result, a plurality of the through holes P₃ penetrating through the photoelectric conversion layer 300 are formed to be spaced apart from each other. Here, the through holes P₃ are not formed along a continuous straight line. The plurality of the through holes P₃ are spaced from each other in the form of a point having a predetermined width and formed on one side of the lower electrode separation groove P₁. Through the through holes P₃ formed in such a manner, the cells within the photovoltaic module are connected in series to each other.

Here, the section of the through hole P₃ has a width greater than that of the section of the insulating groove P₂ such that the through hole P₃ is fully inserted into and passes through the insulating groove P₂. Thus, the insulating groove P₂ insulates the through hole P₃ from the intermediate reflector 320 and/or the p-type semiconductor layer contacting with the intermediate reflector 320.

As shown in FIG. 3h, the upper electrode 400 is formed to cover the photoelectric conversion layer 300 and the through hole P₃. The upper electrode 400 may include a conductive material which well reflects light and functions as an electrode. For example, the conductive material constituting the upper electrode 400 may include Al, Ag, Au, Cu, Zn, Ni, Pt, Pd and Cr and the like. Since the conductive material forming the upper electrode 400 is filled in the through hole P₃, the lower electrode 200 of the first cell and the upper electrode 400 of the other second cell among the adjacent cells can be electrically connected to each other.

In addition, when the photovoltaic module according to the embodiment of the present invention performs photoelectric conversion by the light irradiated from the upper electrode 400, the upper electrode 400 can be formed of a transparent conductive material. In this case, the lower electrode 200 may include a conductive material which well reflects light and functions as an electrode.

As shown in FIG. 3i, laser is irradiated from the atmosphere, and then the photoelectric conversion layer 300 and the upper electrode 400 are scribed. As a result, the upper separation groove P₄ penetrating through the photoelectric conversion layer 300 and the upper electrode 400 is formed along the second line 420. With the exception of a portion of the second line 420, which surrounds the point type through hole P₃, the second line 420 follows the same path as the first line 220 in which the lower electrode separation groove P₁ is formed. That is, with the exception of a portion of the upper separation groove P₃, which surrounds the through hole P₃, the upper separation groove P₄ is formed to pass over the lower electrode separation groove P₁. The unit cells UC₁ and UC₂ are defined by the upper separation groove P₄.

According to another embodiment of the present invention, the forming of the upper electrode in vacuum and the forming of the upper separation groove P₄ by performing laser scribing in atmospheric air can be replaced with a printing of the patterned upper electrode in a non-vacuum environment. For example, the upper electrode patterned by the shape of the second line 420 can be formed in a non-vacuum environment on the photoelectric conversion layer 300 by a printing method such as laser printing, inkjet printing and screen printing and the like. Since the patterned upper electrode is formed in the atmosphere not in vacuum, manufacturing cost can be reduced.

In the manufacturing process described above of the photovoltaic module according to the embodiment of the present invention, while it is described that the lower electrode separation groove P₁ is formed along the first line 220 and the upper separation groove P₄ is formed along the second line 420, it is also possible that the lower electrode separation groove P₁ is formed along the second line 420 and the upper separation groove P₄ is formed along the first line 220.

Here, a ratio of an overlapped length of the upper separation groove and the lower electrode separation groove to the length of the first line may be equal to or greater than 0.70 and equal to and less than 0.96. When the ratio is less than 0.70, the ineffective area is increased, so that electric current cannot sufficiently rise and manufacturing time may be increased. When the ratio is greater than 0.96, the path of the electron is increased, so that an electrical resistance and Joule heat are increased, and then fill factor of the photovoltaic module may be reduced.

Besides, in FIG. 1 and the manufacturing process described above of the photovoltaic module according to the embodiment of the present invention, while it is described that the width of the lower electrode separation groove P₁ is greater than that of the upper separation groove P₄, this is just an example. It is also possible that the width of the lower electrode separation groove P₁ may be equal to or less than that of the upper separation groove P₄.

In the manufacturing process described above of the photovoltaic module according to the embodiment of the present invention, at least one of the lower electrode separation groove P₁, the insulating groove P₂, the through hole P₃ and the upper separation groove P₄ can be formed by laser scribing. A laser processing machine (not shown) performing a laser scribing may include a homogenizer such that the intensity distribution of a laser beam oscillated from the laser oscillator are uniformized in a laser beam irradiation area. The homogenizer may be formed through a combination of spherical lenses or formed of an optical fiber cable which utilizes total reflection characteristics.

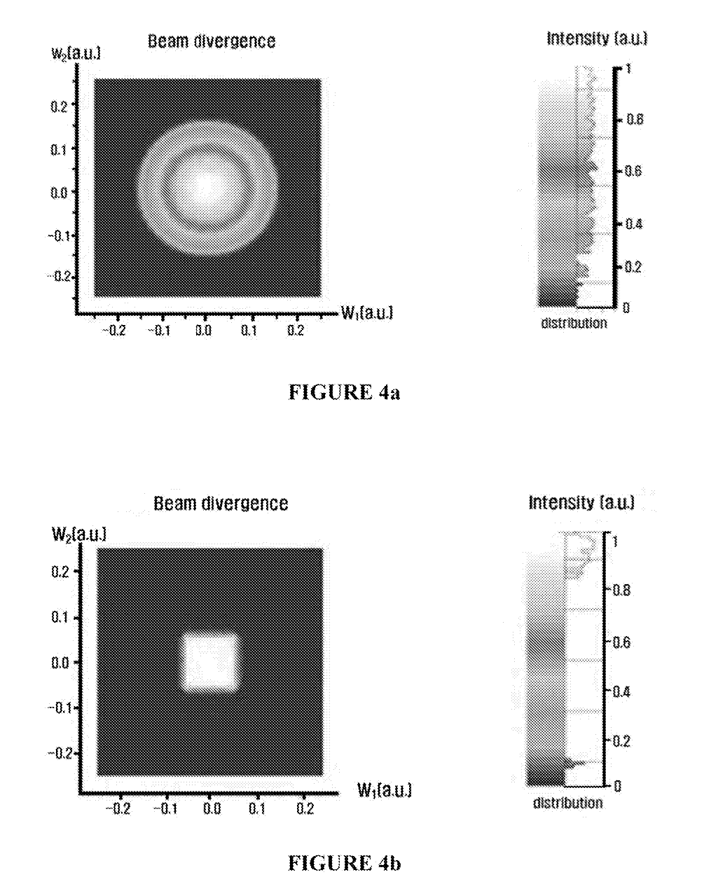

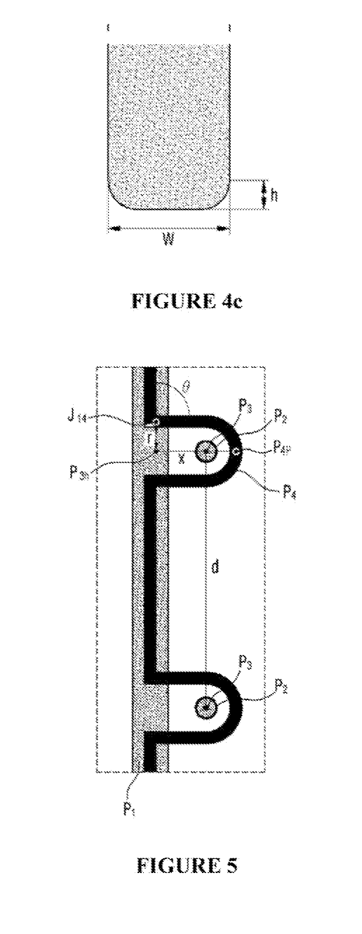

Referring to FIGS. 4a and 4b, when a laser beam which is oscillated from the laser oscillator and has a Gaussian intensity distribution passes through the homogenizer, the laser beam becomes to have a uniform intensity distribution. Additionally, referring to FIGS. 4a and 4b, it can be understood that a pattern surface formed by using the laser beam having a Gaussian intensity distribution (FIG. 4a) is much more irregular than a pattern surface formed by using a laser beam which passes through the homogenizer and has a uniform intensity distribution (FIG. 4b).

In other words, when the intensity distribution of a laser beam becomes uniform, pattern surfaces of the separation grooves formed by irradiating the laser beam is substantially uniformly formed. Accordingly, it is possible to minimize the generation of burr in the side walls of the lower electrode separation groove, the insulating groove, the through hole and/or the upper separation groove P₁, P₂, P₃ and P₄, so that an integrated thin-film photovoltaic module having improved efficiency can be manufactured. Further, by using the laser beam which has passed through the homogenizer, it is possible to prevent the peripheral photoelectric conversion layer and characteristics of the electrode from being changed by the laser power for desired insulation characteristics.

Additionally, the laser processing machine may include a mask having a predetermined pattern formed therein, which allows the laser beam which has passed through the homogenizer to be selectively transmitted therethrough. As a result, only a laser beam area showing a desired uniform intensity distribution can be used to form the separation groove, the insulating groove or the through hole.

FIG. 4c shows a section of either the separation groove pattern, the insulating groove pattern or the through hole pattern which is formed according to the embodiment of the present invention. Here, it is recommended that a ratio of a level difference “h” of the bottom surface of the pattern to the width “W” of the pattern be equal to or greater than 5% and equal to or less than 10%. When the ratio of the level difference “h” of the bottom surface of the pattern to the width “W” of the pattern is greater than 10%, the edge of the pattern is not sufficiently removed and leak current may be generated. In order that the ratio of the level difference “h” to the width “W” of the pattern may be less than 5%, an excessive laser power is added. As a result, the peripheral photoelectric conversion layer and the characteristics of the electrode may be changed.

In the photovoltaic module including the photovoltaic cells connected in series to each other by the point contact in accordance with the one embodiment of the present invention, it is important that an appropriate number of the through holes P₃ be formed. When the number of the through hole P₃ is very large, the ineffective area is increased like the straight line type laser scribing, so that electric current cannot sufficiently rise. Moreover, since the upper separation groove P₄ formed by the laser scribing is formed to surround the through hole P₃, manufacturing time may be increased. When the number of the through holes P₃ is very small, a path through which the electron should move is increased, so that the electrical resistance and Joule heat are increased and then fill factor may be reduced. Therefore, it is necessary to optimize the number of the through holes P₃ and the distance between the plurality of the through holes P₃ formed between the two adjacent unit cells.

FIG. 5 shows an enlarged view of a dotted-line quadrangular part “A” of FIG. 1. “d” represents a distance between the two adjacent through holes P₃. “x” represents a distance between the first line 220 and the through hole P₃. “P₃ₕ” represents a foot of perpendicular, which extends from the through hole P₃ to the first line 220. “J₁₄” represents a branch point from which the lower electrode separation groove P₁ and the upper separation groove P₄ branch from each other. “r” represents a distance between the P₃ₕ and J₁₄.

As shown in FIG. 5, the second line 420 is overlapped with the first line 220 with the exception of the areas surrounding the through hole P₃. That is, the second line 420 branches off from the point “J₁₄” on the first line 220, which is spaced from the foot of perpendicular “P₃ₕ” at a predetermined distance “r” and surrounds the through hole P₃, and then may return to another point on the first line 220, which is spaced from the foot of perpendicular “P₃ₕ” at the predetermined distance “r”.

Here, the second line 420 may be located in the middle between the foot of perpendicular “P₃ₕ” and the outermost point “P₄ₚ” from the first line 220. A distance between the second line 420 and the foot of perpendicular “P₃ₕ” is represented by “2×”.

In the photovoltaic module according to the embodiment of the present invention, the distance “2×” may be equal to or greater than 300 μm and equal to or less than 400 μm. As long as the distance “2×” is maintained within the range, it is possible not only to prevent short-circuit of the insulating groove P₂ and the through hole P₃ between the lower electrode separation groove P₁ and the upper separation groove P₄ but also to prevent the size of the ineffective area from being unnecessarily increased.

In the photovoltaic module according to the embodiment of the present invention, it is recommended that a distance “d” between the through holes P₃ be equal to or greater than 1 mm and equal to or less than 5 cm. Here, a ratio of the distance “2×”, i.e., the distance between the second line 420 and the foot of perpendicular “P₃ₕ” to the distance “d” between the through holes P₃ may be equal to or greater than 6×10⁻³ and equal to or less than 400×10⁻³. When the distance “d” is less than 1 mm, the ineffective area is increased, so that electric current cannot sufficiently rise and manufacturing time may be increased. When the distance “d” is greater than 5 cm, a path through which the electron should move to the lower electrode is increased, so that the electrical resistance and Joule heat are increased and then fill factor of the photovoltaic module may be reduced.

The unit cells UC₁ and UC₂ of the photovoltaic module according to the embodiment of the present invention have a width which is equal to or greater than 6 mm and equal to or less than 15 mm. When the width of the cell is less than 6 mm, the ineffective area is increased and the value of the open circuit voltage (Voc) generated by one module becomes larger, so that installation cost is increased. When the width of the cell is greater than 15 mm, the electrical resistance increases and the efficiency of the manufactured photovoltaic module is degraded.

In the module, when a remaining area which is obtained by removing semiconductors and conductors for the purpose of edge isolation and performs photoelectric conversion is referred to as an effective area, in the photovoltaic module according to the embodiment of the present invention, the ineffective area by the laser scribing to the effective area may be equal to greater than 0.015% and equal to or less than 2.7%.

In the photovoltaic module according to the embodiment of the present invention, a shape in which the second line 420 surrounds the through hole P₃ can be determined such that an electron path from the through hole P₃ to the second line 420 becomes as short as possible. When the electron path from the through hole P₃ to the upper separation groove P₄ surrounding the through hole P₂ is as short as possible, minimum heat can be generated. The shape is formed to have the same distance from the through holes P₃, thereby minimizing the ineffective area generated therefrom. For example, the upper separation groove P₄ surrounding the through hole P₃ may have a partial circular shape. For example, the second line 420 surrounds the through hole P₃ in the form of the partial circular shape.

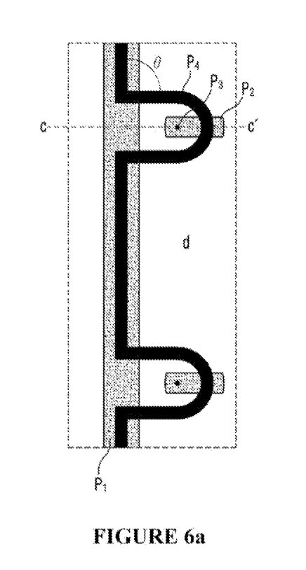

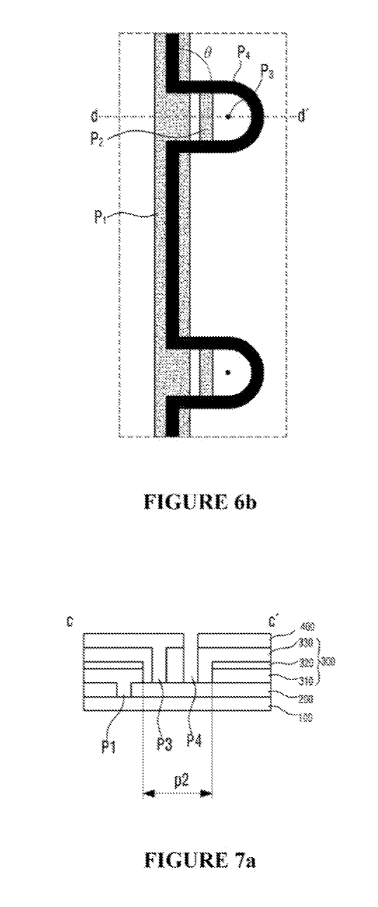

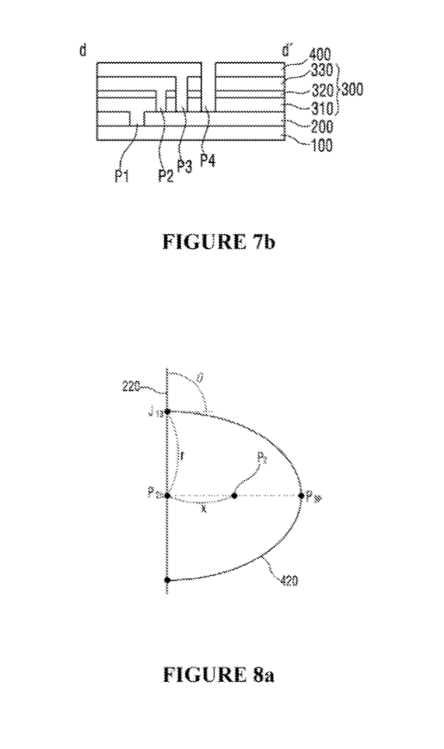

FIG. 5 shows that the insulating groove P₂ is penetrated by the through hole P₃ and is surrounded by the upper separation groove P₄. This is only an example and when the insulating groove P₂ is, as shown in FIG. 6a, viewed from the upper electrode of the photovoltaic module, the upper separation groove P₄ may be formed to cross the insulating groove P₂. FIG. 7a is a cross sectional view taken along line c-c′ of FIG. 6a. Here, it can be found that the width of the insulating groove P₂ is great enough for the through hole P₃ and the upper separation groove P₄ to be formed within the insulating groove P₂.

When the through hole P₃ is fully inserted into the insulating groove P₂ such that the through hole P₃ is insulated from the conductive intermediate reflector 320 and/or the p-type semiconductor layer contacting with intermediate reflector, the width or the shape of the insulating groove P₂ may be variously changed. However, when the width of the insulating groove P₂ becomes unnecessarily greater, the efficiency of the photovoltaic module may be degraded.

The insulating groove P₂ may have a polygonal shape, a circular shape or an elliptical shape. Preferably, when the shape of the insulating groove P₂ is determined to be matched to the shape of the through hole P₃, insulation is appropriately maintained and current collection efficiency is prevented from being unnecessarily degraded. For example, when the through hole P₃ has a circular shape or a regular polygonal shape, it is recommended that the shape of the insulating groove P₂ should also have a circular shape or a regular polygonal shape and their centers be aligned with each other. The shape of the insulating groove P₂ can be formed by including a mask having a predetermined pattern formed therein such that the laser beam which has passed through the homogenizer can be selectively transmitted to the laser processing machine.

FIG. 6b shows enlarged views of a dotted-line quadrangular part “A” of FIG. 1 according to another embodiment of the present invention. Particularly, shown is another embodiment of the insulating groove P₂ for preventing leak current generated from the contact of the intermediate reflector with the upper electrode 400 material filled in the through hole P₃. That is, insulating groove P₂ is formed to form a closed loop with the upper separation groove P₄ in an area where the upper separation groove P₄ branches off from the lower electrode separation groove P₁ and surrounds the through hole P₃. Here, the through hole P₃ may be located within the closed loop formed by the insulating groove P₂ and the upper separation groove P₄. Here, the insulating groove P₂ may be formed to form the closed loop surrounding the through hole P₃. That is, the insulating groove P₂ is able to form the closed loop with the upper separation groove P₄, and also only the insulating groove P₂ is able to form the closed loop surrounding the through hole P₃.

The through hole P₃ contacts with the conductive intermediate reflector 320 located within the closed loop and/or the p-type semiconductor layer contacting with the intermediate reflector. However, since the intermediate reflector 320 and/or the p-type semiconductor layer contacting with the intermediate reflector are insulated from the intermediate reflectors of the adjacent cells by the insulating groove P₂ and the upper separation groove P₄, all of which form the closed loop, leak current can be prevented from being generated.

FIG. 7b is a cross sectional view taken along line d-d′ of FIG. 6b. Here, it can be found that the intermediate reflector 320 contacting with the through hole P₃ is insulated from the intermediate reflectors of the adjacent cells by the insulating groove P₂ and the upper separation groove P₄.

In this specification, it should be noted that the fact that the through hole P₃ is located within the closed loop does not preclude a case where the through hole P₃ is overlapped with the insulating groove P₂. In other words, the insulating groove P₂ is formed wider than the insulating groove P₂ shown in FIG. 6b, and may be overlapped with a portion or the entire of the through hole P₃. However, even in this case, the through hole P₃ should be insulated from the upper separation groove P₄.

Besides, as long as the upper separation groove P₄ and the insulating groove P₂ form a closed loop surrounding the through hole P₃, the insulating groove P₂ may have any length or any shape. For example, both ends of the insulating groove P₂ may contact with and extend from the upper separation groove P₄. The insulating groove P₂, like the lower electrode separation groove P₁, may be formed along the first line 220.

Depending on another embodiment of the present invention, even when the upper separation groove P₄ is formed along the straight line type first line 220 and the lower electrode separation groove P₁ is formed along the second line 420, the insulating groove P₂ is formed to form the closed loop with the upper separation groove P₄, so that leak current can be prevented. Here, the through hole P₃ is located within the closed loop which is formed by the insulating groove P₂ and the upper separation groove P₄.

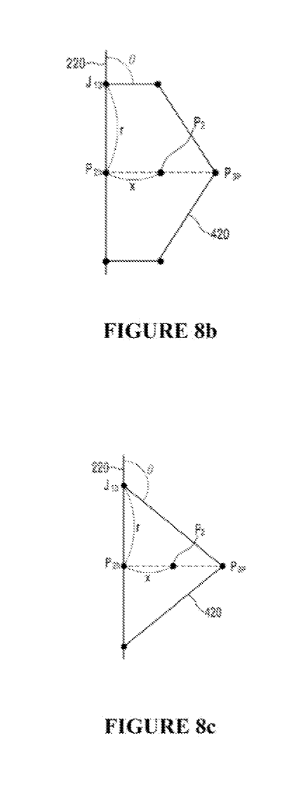

FIGS. 8a to 8c show another example of a shape in which the upper separation groove P₄ surrounds the through hole P₃ in the photovoltaic module according to the embodiment of the present invention.

FIG. 8a shows that the second line 420 branches off from the branch point “J₁₄” on the first line 220 and surrounds the through hole P₃ along a part of an ellipse. Here, the through hole P₃ may be located in the middle between the foot of perpendicular “Pₘ” and the outermost point “P₄ₚ” of the second line 420. When the second line 420 surrounds the through hole P₃ along a partial ellipse or circle, distances from the through hole P₃ to the second line 420 are somewhat uniform and the ineffective area can be reduced.

FIGS. 8b and 8c show that the second line 420 surrounds the through hole P₃ in a partial pentagon and triangle. It can be noted that also when the second line 420 surrounds the through hole P₃ in such shapes, the ineffective area can be reduced and the distances from the through hole P₃ to the second line 420 are somewhat uniform.

However, the shapes shown above are just examples. The specific shapes of the photovoltaic module according to the embodiment of the present invention may be a partial polygon including the pentagon or triangle. Here, only when all of the interior angles of the polygon are less than 180°, the ineffective area can be efficiently reduced. Also, it is recommended that the polygon be symmetrical with respect to a line connecting the foot of perpendicular “P₃ₕ”, the through hole P₃ and the outermost point “P₄ₚ”. Also, it is desirable that all of the interior angles of the polygon be equal to or greater than 90°. When the interior angle of the polygon is an acute angle, the laser beam is focused on the same vertex, so that, patterning is excessively done or the photoelectric conversion layer and an electrode layer may be damaged by heat.

However, an angle “θ” formed at the branch point “J₁₄” by the first line 220 and the second line 420 may be equal to or greater than 90° and equal to or less than 135°. For example, when the shape is a partial circle or ellipse, an angle formed by the first line 220 and a tangent line at the branch point “J₁₄” of the circle or the ellipse is equal to or greater than 90° and equal to or less than 135°. When the shape is the partial polygon described above, an external angle of the polygon at the branch point “J₁₄” may be equal to or greater than 90° and equal to or less than 135°. When the angle “θ” is less than 90°, the distance between the second line 420 and the through hole P₃ are increased and the ineffective area cannot be efficiently reduced. Also, when the angle “θ” is greater than 135°, the width of the second line 420 surrounding the through hole P₃ is increased and the effect of reducing the ineffective area is degraded.

Also, a point shape of the through hole P₃ may have a circular shape, an elliptical shape or a polygonal shape in accordance with the shape surrounding the through hole P₃. The shape of the through hole P₃ can be obtained by including a mask having a predetermined pattern formed therein such that the laser beam which has passed through the homogenizer can be selectively transmitted to the laser processing machine. As such, the shape of the through hole P₃ is matched to the shape surrounding the through hole P₃, thereby reducing and uniformizing the path through which the electron moves from the through hole P₃ through the lower electrode to the second line 420 surrounding the through hole P₃.

While the embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A tandem type integrated photovoltaic module comprising a first cell and a second cell, all of which are formed respectively by stacking on a substrate a lower electrode, a photoelectric conversion layer and an upper electrode,
wherein the photoelectric conversion layer comprises a first unit cell layer, a second unit cell layer and an intermediate reflector located between the first unit cell layer and the second unit cell layer;
wherein the lower electrode of the first cell and the lower electrode of the second cell are separated by a lower electrode separation groove, and
wherein a plurality of through holes are formed to be spaced from each other in the photoelectric conversion layer on the lower electrode of the first cell in order to connect the upper electrode of the second cell with the lower electrode of the first cell.

2. The tandem type integrated photovoltaic module of claim 1, wherein the photoelectric conversion layer and the upper electrode of the first cell are separated by an upper separation groove from the photoelectric conversion layer and the upper electrode of the second cell, and wherein a portion of the upper separation groove passes over the lower electrode separation groove.

3. The tandem type integrated photovoltaic module of claim 2, wherein an insulating groove is formed in the intermediate reflector on the lower electrode of the first cell such that the insulating groove penetrates through the intermediate reflector, and the through hole passes through the insulating groove.

4. The tandem type integrated photovoltaic module of claim 2, wherein an insulating groove is formed in the intermediate reflector on the lower electrode of the first cell and penetrates through the intermediate reflector, and wherein the insulating groove is formed to form a closed loop with the upper separation groove and to allow the through hole to be located within the closed loop.

5. The tandem type integrated photovoltaic module of claim 3, wherein the through hole is filled with a conductive material, and wherein the insulating groove is filled with the second unit cell layer.

6. The tandem type integrated photovoltaic module of claim 3, wherein the first unit cell layer and the second unit cell layer respectively comprise a p-type semiconductor layer, an intrinsic semiconductor layer and an n-type semiconductor layer, and wherein the insulating groove penetrates through the intermediate reflector and the p-type semiconductor layer contacting with the intermediate reflector.

7. The tandem type integrated photovoltaic module of claim 3, wherein one separation groove of the lower electrode separation groove and the upper separation groove has a straight line shape.

8. The tandem type integrated photovoltaic module of claim 7, wherein a ratio of the length of the portion of the upper separation groove passing over the lower electrode separation groove to the length of the one separation groove is equal to or greater than 0.70 and equal to and less than 0.96.

9. The tandem type integrated photovoltaic module of claim 7, wherein, in an area where the upper separation groove does not pass over the lower electrode separation groove, the other separation groove of the lower electrode separation groove and the upper separation groove has a partial circular shape or a partial elliptical shape.

10. The tandem type integrated photovoltaic module of claim 9, wherein, at a branch point from which the other separation groove branches off the straight line, an angle formed by the straight line and a tangent line of the circle or the ellipse is equal to or greater than 90° and equal to or less than 135°.

11. The tandem type integrated photovoltaic module of claim 7, wherein, in an area where the upper separation groove does not pass over the lower electrode separation groove, the other separation groove of the lower electrode separation groove and the upper separation groove has a partial polygonal shape.

12. The tandem type integrated photovoltaic module of claim 11, wherein, at a branch point from which the other separation groove branches off the straight line, an external angle of the polygon is equal to or greater than 90° and equal to or less than 135°, and wherein all of the interior angles of the polygon are less than 180°.

13. The tandem type integrated photovoltaic module of claim 7, wherein, in an area where the upper separation groove does not pass over the lower electrode separation groove, the through hole is located in the middle between a foot of perpendicular which extends from the through hole to the straight line and the outermost point of the other separation groove of the upper separation groove and the lower electrode separation groove.

14. The tandem type integrated photovoltaic module of claim 3, wherein the widths of the first cell and the second cell are equal to or greater than 6 mm and equal to or less than 15 mm respectively.

15. The tandem type integrated photovoltaic module of claim 3, wherein a distance between two adjacent through holes among the through holes is equal to or greater than 1 mm and equal to or less than 5 cm.

16. The tandem type integrated photovoltaic module of claim 3, wherein, in the integrated thin-film photovoltaic module, a ratio of an ineffective area by the lower electrode separation groove, the insulating groove, the through hole and the upper separation groove to an effective area is equal to or greater than 0.015% and equal to or less than 2.7%.

17. The tandem type integrated photovoltaic module of claim 7, wherein two adjacent through holes among the through holes are spaced from each other at a predetermined distance, and wherein a ratio of a distance between a foot of perpendicular which extends from the through hole to the straight line and the outermost point of the other separation groove of the upper separation groove and the lower electrode separation groove to the predetermined distance is equal to or greater than 6×10⁻³ and equal to or less than 400×10⁻³.

18. The tandem type integrated photovoltaic module of claim 3, wherein the section of the through hole has a circular shape, an elliptical shape or a polygonal shape.

19. The tandem type integrated photovoltaic module of claim 3, wherein, in at least one of the lower electrode separation groove, the insulating groove, the through hole and the upper separation groove, a ration of level difference of the bottom surface to the width is equal to or greater than 5% and equal to or less than 10%.

20. The tandem type integrated photovoltaic module of claim 4, wherein the through hole is filled with a conductive material, and wherein the insulating groove is filled with the second unit cell layer.

21. The tandem type integrated photovoltaic module of claim 4, wherein the first unit cell layer and the second unit cell layer respectively comprise a p-type semiconductor layer, an intrinsic semiconductor layer and an n-type semiconductor layer, and wherein the insulating groove penetrates through the intermediate reflector and the p-type semiconductor layer contacting with the intermediate reflector.

22. The tandem type integrated photovoltaic module of claim 4, wherein one separation groove of the lower electrode separation groove and the upper separation groove has a straight line shape.

23. The tandem type integrated photovoltaic module of claim 4, wherein the widths of the first cell and the second cell are equal to or greater than 6 mm and equal to or less than 15 mm respectively.

24. The tandem type integrated photovoltaic module of claim 4, wherein a distance between two adjacent through holes among the through holes is equal to or greater than 1 mm and equal to or less than 5 cm.

25. The tandem type integrated photovoltaic module of claim 4, wherein, in the integrated thin-film photovoltaic module, a ratio of an ineffective area by the lower electrode separation groove, the insulating groove, the through hole and the upper separation groove to an effective area is equal to or greater than 0.015% and equal to or less than 2.7%.

26. The tandem type integrated photovoltaic module of claim 4, wherein the section of the through hole has a circular shape, an elliptical shape or a polygonal shape.

27. The tandem type integrated photovoltaic module of claim 4, wherein, in at least one of the lower electrode separation groove, the insulating groove, the through hole and the upper separation groove, a ration of level difference of the bottom surface to the width is equal to or greater than 5% and equal to or less than 10%.

28. A manufacturing method of a tandem type integrated photovoltaic module, the method comprising:
forming a lower electrode layer on a substrate;
forming a lower electrode separation groove separating the lower electrode layer into a first cell lower electrode layer and a second cell lower electrode layer;
forming a photoelectric conversion layer including a first unit cell layer, an intermediate reflector and a second unit cell layer on the first cell lower electrode layer and a second cell lower electrode layer;
forming a plurality of through holes which are spaced from each other and penetrate through the photoelectric conversion layer on the first cell lower electrode layer;
forming an upper electrode layer within the through hole and on the photoelectric conversion layer; and
forming an upper separation groove which separates the upper electrode layer and the photoelectric conversion layer and of which a portion passes over the lower electrode separation groove.

29. The manufacturing method of claim 28, wherein the forming the photoelectric conversion layer comprises:
forming the first unit cell layer;
forming the intermediate reflector on the first unit cell layer;
forming an insulating groove which penetrates through the intermediate reflector on the first cell lower electrode layer and through which the through hole passes; and
forming the second unit cell layer within the insulating groove and on the intermediate reflector.

30. The manufacturing method of claim 28, wherein the forming the photoelectric conversion layer comprises:
forming the first unit cell layer;
forming the intermediate reflector on the first unit cell layer;
forming an insulating groove, which penetrates through the intermediate reflector, in the intermediate reflector on the lower electrode of the first cell such that the insulating groove forms a closed loop with the upper separation groove and the through hole is located within the closed loop; and
forming the second unit cell layer within the insulating groove and on the intermediate reflector.

31. The manufacturing method of claim 29, wherein the forming the insulating groove comprises forming the insulating groove penetrating through the intermediate reflector and the first unit cell layer.

32. The manufacturing method of claim 29, wherein the first unit cell layer and the second unit cell layer respectively comprise a p-type semiconductor layer, an intrinsic semiconductor layer and an n-type semiconductor layer, all of which are stacked in the order listed, and wherein the forming the photoelectric conversion layer comprises:
forming the p-type semiconductor layer, the intrinsic semiconductor layer and the n-type semiconductor layer of the first unit cell layer;
forming the intermediate reflector on the first unit cell layer;
forming the p-type semiconductor layer of the second unit cell layer on the intermediate reflector;
forming the insulating groove in such a manner as to penetrate through the intermediate reflector and the p-type semiconductor layer of the second unit cell layer; and
forming the intrinsic semiconductor layer and the n-type semiconductor layer of the second unit cell layer within the insulating groove and on the p-type semiconductor layer of the second unit cell layer.

33. The manufacturing method of claim 32, wherein the forming the insulating groove comprises forming the insulating groove penetrating through the first unit cell layer, the intermediate reflector and the p-type semiconductor layer of the second unit cell layer.

34. The manufacturing method of claim 29, wherein the first unit cell layer and the second unit cell layer respectively comprise an n-type semiconductor layer, an intrinsic semiconductor layer and a p-type semiconductor layer, all of which are stacked in the order listed, and wherein the forming the photoelectric conversion layer comprises:
forming the n-type semiconductor layer, the intrinsic semiconductor layer and the p-type semiconductor layer of the first unit cell layer;
forming the intermediate reflector on the first unit cell layer;
forming the insulating groove in such a manner as to penetrate through the intermediate reflector and the p-type semiconductor layer of the first unit cell layer; and
forming the n-type semiconductor layer, the intrinsic semiconductor layer and the p-type semiconductor layer of the second unit cell layer within the insulating groove and on the intermediate reflector.

35. The manufacturing method of claim 34, wherein the forming the insulating groove comprises forming the insulating groove penetrating through the first unit cell layer and the intermediate reflector.

36. The manufacturing method of claim 30, wherein the forming the insulating groove comprises forming the insulating groove penetrating through the intermediate reflector and the first unit cell layer.

37. The manufacturing method of claim 30, wherein the first unit cell layer and the second unit cell layer respectively comprise a p-type semiconductor layer, an intrinsic semiconductor layer and an n-type semiconductor layer, all of which are stacked in the order listed, and wherein the forming the photoelectric conversion layer comprises:
forming the p-type semiconductor layer, the intrinsic semiconductor layer and the n-type semiconductor layer of the first unit cell layer;
forming the intermediate reflector on the first unit cell layer;
forming the p-type semiconductor layer of the second unit cell layer on the intermediate reflector;
forming the insulating groove in such a manner as to penetrate through the intermediate reflector and the p-type semiconductor layer of the second unit cell layer; and
forming the intrinsic semiconductor layer and the n-type semiconductor layer of the second unit cell layer within the insulating groove and on the p-type semiconductor layer of the second unit cell layer.

38. The manufacturing method of claim 30, wherein the first unit cell layer and the second unit cell layer respectively comprise an n-type semiconductor layer, an intrinsic semiconductor layer and a p-type semiconductor layer, all of which are stacked in the order listed, and wherein the forming the photoelectric conversion layer comprises:
forming the n-type semiconductor layer, the intrinsic semiconductor layer and the p-type semiconductor layer of the first unit cell layer;
forming the intermediate reflector on the first unit cell layer;
forming the insulating groove in such a manner as to penetrate through the intermediate reflector and the p-type semiconductor layer of the first unit cell layer; and
forming the n-type semiconductor layer, the intrinsic semiconductor layer and the p-type semiconductor layer of the second unit cell layer within the insulating groove and on the intermediate reflector.
